(19) United States
(12) Patent Application Publication
(10) Pub. No.: US 2007/0139238 A1
(43) Pub. Date: Jun. 21, 2007

(54) Input signal dependent signal conditioning

(75) Inventor: Robert Hendrikus Margaretha Van Veldhoven, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 10/598,226

(22) PCT Filed: Feb. 28, 2005
(86) PCT No.: PCT/IB05/50712

§ 371 Date: Aug. 22, 2006

(30) Foreign Application Priority Data
Mar. 2, 2004 (EP) 04100835.0

(51) Int. Cl. H03M 1/00

(52) U.S. Cl. 341/126

(57) ABSTRACT

A circuit has an analog to digital converter (33) for digitally processing a sensor signal. The sensor signal has signal components representing information (31) and further signal components (32), e.g. bias current or interference. Before converting the sensor signal to the digital domain the input signal is conditioned depending on the characteristics of the input signal. Thereto the device comprises a signal conditioning circuit for receiving the sensor signal and outputting a conditioned sensor signal. The signal conditioning circuit has an analog feedback loop (25) having a loop filter (23) having a transfer function for enhancing the information signal component and reducing the further signal component. This has the advantage that the dynamic range and other requirements for the analog to digital converter are reduced. In particular the circuit is coupled to an electret microphone in a mobile telephone or hearing aid.

The invention relates to a device for digitally processing a sensor signal from a sensor, the sensor signal comprising an information signal component representing information and a further signal component not representing information.

The invention further relates to an audio device, in particular a mobile phone or a hearing aid, comprising the device for digitally processing a sensor signal, and a microphone unit as the sensor.

The invention relates to the field of digital signal processing, and in particular to providing an interface to a microphone and processing the audio signal from a microphone.

The document US 2002/0071578 describes an analog to digital (A/D) converter with integrated biasing for a microphone, i.e. a sensor generating a sensor signal that has an information signal component representing information. In addition the sensor signal contains a DC current as a further signal component not representing information. In particular a combination of an electret microphone and a sigma-delta A/D converter is described. The A/D converter output has a digital DC feedback loop which provides the bias current for a junction FET included in the electret microphone unit. In addition a feedback loop for AC signals is provided. The digital signal from the feedback loops is converted to an analog signal by a DAC (digital to analog converter). The signal current from the microphone is injected directly into an input integrator of the sigma-delta A/D converter, without the need of additional resistors for providing the bias current. However, the feedback loops need digital filtering, which is complicated. In addition, although the sigma-delta output is basically a single bit output, the filter output is a multibit output, which may cause non linearity requiring further linearization circuits. In particular the DAC circuit needs to be highly linear. Hence the known circuit is complicated and requires a relative large chip area when integrated.

It is an object of the invention to provide a device for digitally processing a sensor signal that is less complicated, while providing a direct interface to the sensor.

For this purpose, according to a first aspect of the invention the device as described in the opening paragraph comprises a signal conditioning circuit for receiving the sensor signal and outputting a conditioned sensor signal, and an analog to digital converter for converting the conditioned sensor signal to a digital sensor signal to be processed, the signal conditioning circuit comprising an analog feedback loop having a loop filter having a transfer function having a first transfer function component for enhancing the information signal component and a second transfer function component for reducing the further signal component.

The measures have the effect that the sensor signal is conditioned in the analog domain by the conditioning circuit, while the loop filter in the analog feedback loop is arranged for substantially reducing unwanted signal components. Secondly, the conditioned sensor signal is converted from analog to digital. The signal conditioning circuit deals with the further signal component, for example providing a DC bias current, resulting in a direct interface with the sensor without additional components external to the device. Hence advantageously the conditioning circuit is separated from the digital processing. Moreover the separate signal conditioning circuit has the advantage that the dynamic range and accuracy of the analog to digital converter are less critical, whereas the total of the circuit is less complex reducing the amount of chip surface required for integration.

The invention is also based on the following recognition. In the art of digital signal processing the signals from the analog sensors are converted to the digital domain, and thereafter processed, filtered, amplified, etc. In particular the skilled man will implement a transition from the analog domain to the digital domain as soon as possible after generating analog sensor signals. The inventor has seen that by first conditioning the sensor signal in the analog domain, the requirements for the A/D converter and front-end digital signal processing can be reduced significantly. Surprisingly the total amount of circuitry for the analog conditioning circuit and the subsequent and less complicated digital signal processing is lower than for comparable digital front end circuits at similar performance levels, in particular when integrated on a chip.

In an embodiment of the device the analog feedback loop comprises a summing element for receiving the sensor signal and an output signal of the loop filter. This has the advantage that unwanted signal components in the sensor signal are compensated by signal components in the output signal of the loop filter.

In an embodiment of the device the first transfer function component is arranged for enhancing in-band signal components in a first frequency band as the information signal component and the second transfer function component is arranged for reducing interference signal components in a second frequency band as the further signal component. This has the advantage that interference signal components are weakened compared to the in-band signal components.

In an embodiment of the device the first transfer function component is arranged for enhancing an AC signal component as the information signal component and the second transfer function component is arranged for reducing a DC signal component as the further signal component. This has the advantage that DC signal components are provided as required for biasing the sensor while AC signal components are amplified.

In an embodiment of the device the sensor is a microphone unit having an amplifying element, in particular an electret condenser microphone having a field effect element, and the second transfer function component is arranged for said reducing by providing a bias current to the amplifying element. This has the advantage that a microphone signal is enhanced while providing the bias current.

Any of the above embodiments of the device for digitally processing a sensor signal from a sensor which may be included in an audio device, in particular a mobile phone or a hearing aid, in combination with a microphone unit as the sensor. This has the advantage that a digital signal processing circuit is directly interfacing with the microphone unit, while the requirements for the analog to digital conversion are reduced.

Further embodiments are given in the dependent claims.

These and other aspects of the invention will be apparent from and elucidated further with reference to the embodiments described by way of example in the following description and with reference to the accompanying drawings, in which:

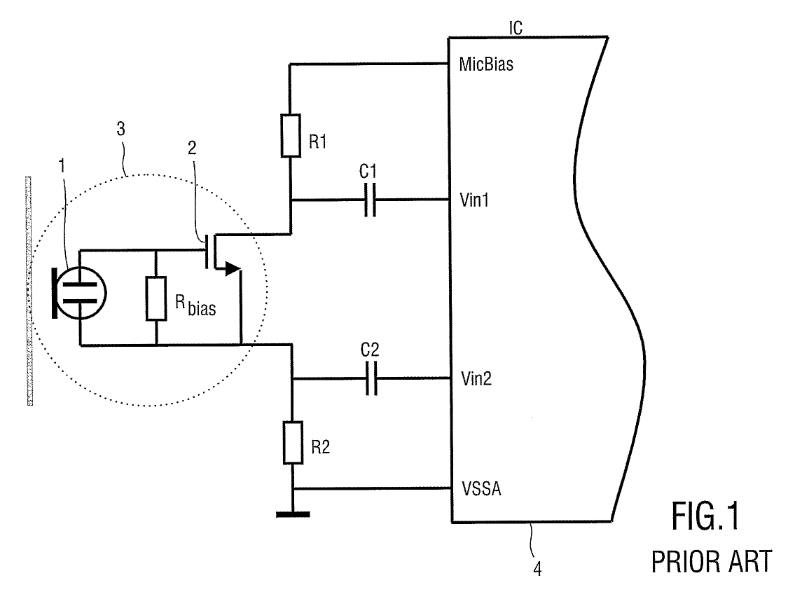

FIG. 1 shows a diagram of a prior-art circuit for biasing an electret microphone,

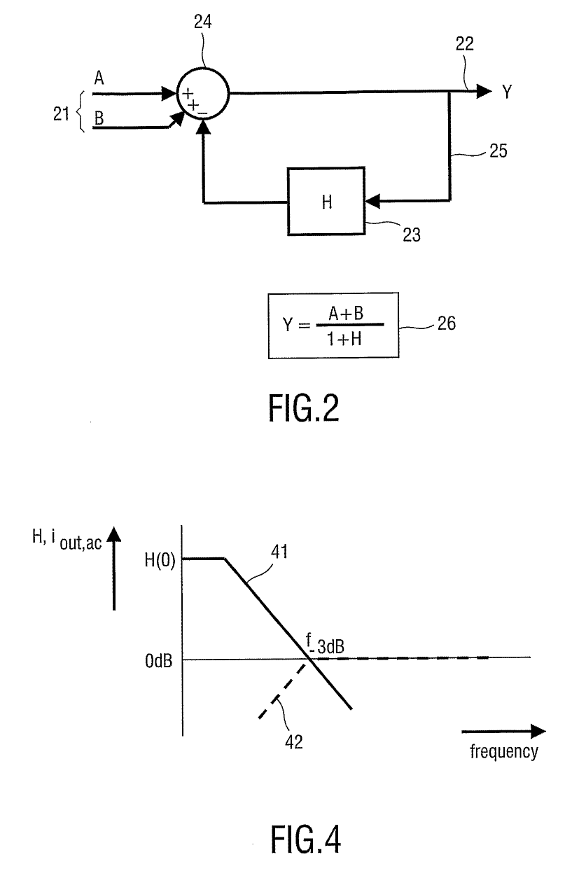

FIG. 2 shows an input signal dependent signal conditioning circuit,

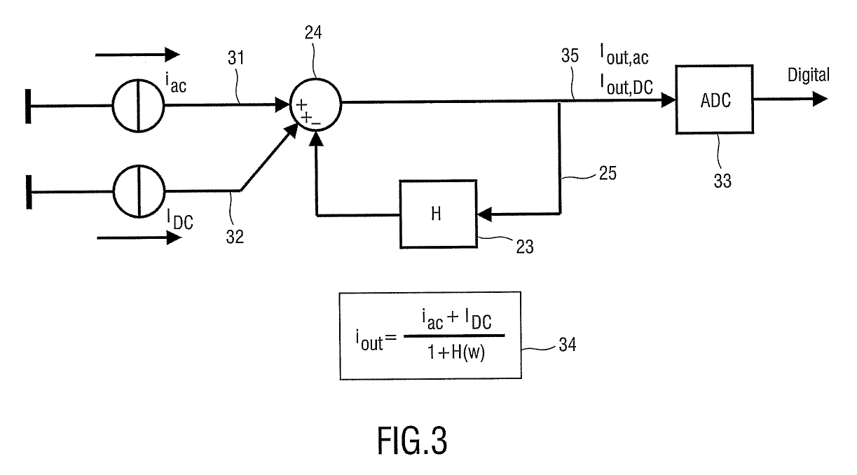

FIG. 3 shows an input signal dependent signal conditioning circuit for a microphone,

FIG. 4 shows a transfer function of a loop filter, and

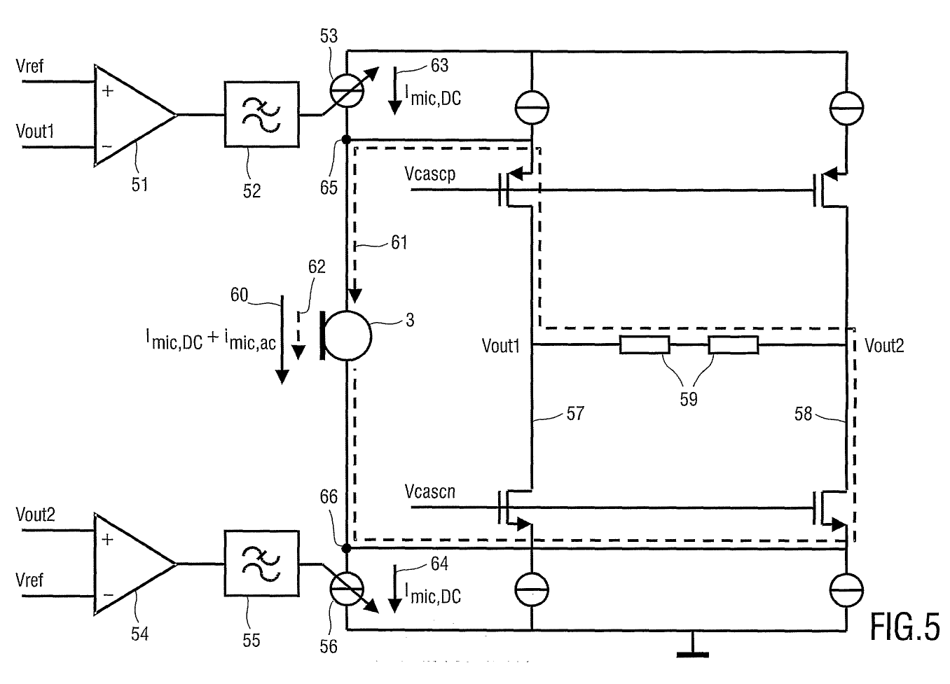

FIG. 5 shows an implementation of the conditioning circuit.

Corresponding elements in different Figures have identical reference numerals.

FIG. 1 shows a diagram of a prior-art circuit for biasing an electret microphone. Applications with a speech input, such as mobile telephones and hearing aids, often use electret capacitor microphones. It is common practice to include a JFET (junction field effect transistor) with an electret element in a housing, and such a combined unit being called the electret microphone. The JFET has its gate connected to one of the terminals of the electret and has its source connected to the other terminal of the electret. Further, a gate bias resistor incorporated in the same housing is connected in parallel with the electret. The JFET is a depletion device, which means that it delivers a direct current if its gate-source voltage VGS=0V. It is noted that different configurations of an electret and semiconductor element may be used, e.g. the electret being connected between the gate and drain of a FET.

To obtain an output signal representing the variations of the air pressure in its vicinity, the combination of electret and JFET requires a bias current. The Figure shows a common circuit for supplying such a bias current to a microphone unit 3, including an electret 1, a gate bias resistor R_{BIAS} and a JFET 2, located within a housing. The circuit comprises two external resistors R1 and R2 for supplying the bias current from the power supply MicBias, and two capacitors C1 and C2, for coupling the signal to the inputs of a subsequent circuit, such as a processing IC 4.

Usually, the DC bias current is about 10 to 50 times as large as the actual AC signal current. The gate bias resistor R_{BIAS} biases the gate of the JFET 2 so as to achieve that its gate-source voltage VGS=0V. In a typical application the combination of JFET 2 and electret microphone 1 delivers a current of 300 μA, which is converted into a voltage by the resistors R1 and R2, typically 1-2 kΩ. The processing IC 4 provides the inputs for the AC microphone signal at V_{IN1} and at V_{IN2}, and the bias current between MicBias and a zero supply terminal Vssa.

With the two capacitors C1 and C2 the output signal of the microphone can for example be connected to an A/D converter which converts the speech signal into the digital domain for further processing. This circuit needs 4 external components, two signal pins and a microphone supply pin, on which a clean supply voltage is generated by the integrated circuit. In summary, this biasing scheme uses 4 components and 3 IC pins.

FIG. 2 shows an input signal dependent signal conditioning circuit. The circuit is arranged for receiving a sensor signal 21 and outputting a conditioned sensor signal 22 at output Y. The conditioned sensor signal is to be coupled to a subsequent analog to digital converter for converting the conditioned sensor signal to a digital sensor signal to be processed in a digital signal processor (not shown). The sensor signal comprises an information signal component (A) representing information and a further signal component (B) not representing information, e.g. a bias current. The signal conditioning circuit has an analog feedback loop 25 having a loop filter 23 coupled to the sensor signal 21 via a summing element 24. The loop filter 23 has a transfer function having a first transfer function component for enhancing the information signal component A and a second transfer function component for reducing the further signal component B. The input signal components A and B have different specifications, for example in frequency and amplitude. The transfer function 26 of the signal conditioning circuit is

$$Y = \frac{A + B}{1 + H}$$

By choosing the transfer function H of the loop filter in a way that gain and frequency response are dependent on the signal properties of the input signal components A and B, signal conditioning is achieved which depends on characteristics of the input signals.

FIG. 3 shows an input signal dependent signal conditioning circuit for a microphone. A microphone output current is analyzed as two components; an AC component 31 and DC component 32. The circuit of FIG. 2 is applied, and the conditioned output signal 22 is given by function 34. For transfer function H(w) of the loop filter 23, which has high gain for low frequencies (DC) and low gain for AC signals (speech signals), the response function i_{out,ac} of the output 35 is given in FIG. 4. The DC component at the output of the signal conditioning circuit is attenuated by the low frequency gain of H(w). If the input DC component is 10 times bigger than the AC input signal, and H(w) has a DC gain of for example 1000, the output DC component will be a 100 times smaller than the AC current.

The conditioning circuit is followed by an A/D converter 33 (ADC). The DC component is not needed in the digital domain, because the intention of the circuit is to convert speech signals into the digital domain. Hence the dynamic range of the ADC can almost be fully used to convert for the AC signal, because the DC component is only 1/100^{th} of the AC signal. So 1/(1+0.01)*100%=99.009% of the ADC's dynamic range is used by useful input signals, while in a circuit directly converting the microphone signal this was 1/(1+10)*100%=9.09%, and a 10 times larger dynamic range was needed to convert the AC signal with the same resolution.

FIG. 4 shows a transfer function of a loop filter. A transfer function H(0) is indicated by a curve 41, the horizontal axis indicating frequency and the vertical axis indicating the response. The resulting frequency response at the output 35 of the conditioning circuit in FIG. 3, denoted as I_{out,ac}, is indicated by a second (dashed) curve 42.

In an embodiment an additional advantage of the conditioning circuit is as follows. For the DC bias current a DC component in the transfer function of the loop filter is applied. Additionally, a suppression of low frequency tones may be achieved by including a low pass filter in the transfer function of the loop filter. For example a 50 Hz interference, which is outside of the speech signal bandwidth (so called in-band signals), is attenuated by the signal conditioning circuit. If H is a first order filter low pass which intersects the 0 dB line at f_{-3 dB}, the AC signal will have a −3 dB point at this frequency, e.g. as indicated in FIG. 4 by f_{-3 dB}. If f_{-3 dB}=100 Hz for example, 50 Hz will be attenuated by 6 dB in this case. Also other low frequency interfering noise will be attenuated, which might be useful when for instance a mobile phone is used in a noisy environment like a car.

FIG. 5 shows an implementation of the conditioning circuit. A first amplifier 51 has a positive input coupled to a reference voltage Vref, which provides a suitable reference DC level for the output Vout1 that is coupled to the negative input. A loop filter 52 provides a low pass function as discussed with FIGS. 3 and 4, and the output of the low pass filter controls a current source 53 that is coupled at a first summing node 65 to a first terminal of a microphone unit 3, for example an electret microphone unit including a JFET as shown in FIG. 1. A second amplifier 54 has a negative input coupled to the reference voltage Vref, which provides a suitable reference DC level for the output Vout2 that is coupled to the positive input. A loop filter 55 provides a low pass function as discussed with FIGS. 3 and 4, and the output of the low pass filter controls a current source 56 that is coupled at a second summing node 66 to a second terminal of the microphone unit 3. Both controlled current sources 53,56 provide a DC bias current I_{mic,DC} indicated by arrows 60, 63 and 64. An AC current from the microphone unit 3 is coupled to a first output amplifier cascade circuit 57 to generate the output Vout1, and to a second output amplifier cascade circuit 58 to generate the output Vout2, as indicated by arrow 61. Each cascade has a series circuit of a positive current source, a positive amplifying FET, a negative amplifying FET and a negative current source. Both the outputs Vout1 and Vout2 provide a differential output signal coupled to a load 59, and further to the ADC (not shown).

The two opamps 51,54 regulate the DC output voltage to the reference voltage (for example half the supply voltage). Because H is implemented as a low pass loop filters 52,55, only the DC output voltage is regulated and the microphone AC output current is forced into the cascades 57,58. This is because the filter is attenuating the AC signal frequencies, and the controlled current sources 53,56 will only deliver a DC component as required by the microphone, and some low AC frequency components which reduce interference. The AC current at higher frequencies (in-band) is converted to the output voltage at load 59, which is used for further signal processing, by for example an A/D converter.

It is noted that FIG. 5 provides a balanced circuit. In an alternative embodiment similar elements are used in a single ended configuration. Then only a single loop and loop low pass filter are required.

Although the invention has been explained mainly by embodiments based on FETs as amplifying semiconductors, it is noted that in the invention may be implemented using any type of analog amplifying elements. Further it is noted, that in this document the word ‘comprising’ does not exclude the presence of other elements or steps than those listed and the word ‘a’ or ‘an’ preceding an element does not exclude the presence of a plurality of such elements, that any reference signs do not limit the scope of the claims, that the invention may be implemented by means of both hardware and software, and that several ‘means’ may be represented by the same item of hardware. Further, the scope of the invention is not limited to the embodiments, and the invention lies in each and every novel feature or combination of features described above.

1. Device for digitally processing a sensor signal from a sensor, the sensor signal comprising an information signal component representing information and a further signal component not representing information,
the device comprising a signal conditioning circuit for receiving the sensor signal and outputting a conditioned sensor signal, and an analog to digital converter (33) for converting the conditioned sensor signal to a digital sensor signal to be processed, the signal conditioning circuit comprising an analog feedback loop (25) having a loop filter (23) having a transfer function having a first transfer function component for enhancing the information signal component and a second transfer function component for reducing the further signal component.

2. Device as claimed in claim 1, wherein the analog feedback loop (25) comprises a summing element (24) for receiving the sensor signal and an output signal of the loop filter.

3. Device as claimed in claim 1, wherein the first transfer function component is arranged for enhancing in-band signal components in a first frequency band as the information signal component and the second transfer function component is arranged for reducing interference signal components in a second frequency band as the further signal component.

4. Device as claimed in claim 1, wherein the first transfer function component is arranged for enhancing an AC signal component (31) as the information signal component and the second transfer function component is arranged for reducing a DC signal component (32) as the further signal component.

5. Device as claimed in claim 1, wherein the sensor is a microphone unit (3) having an amplifying element, in particular an electret condenser microphone having a field effect amplifying element, and the second transfer function component is arranged for said reducing by providing a bias current to the amplifying element.

6. Device as claimed in claim 1, wherein the signal conditioning circuit comprises a first analog feedback loop (51, 53) from a first output (Vout1), which first loop includes a first loop filter (52) coupled to a first summing element (65), and a second analog feedback loop (54, 56) from a second output (Vout2), which second loop includes a second loop filter (55) coupled to a second summing element (66), both outputs providing a differential output signal.

7. Audio device, in particular a mobile phone or a hearing aid, comprising a device for digitally processing a sensor signal from a sensor as claimed in claim 1, and a microphone unit as the sensor.
